(19) United States
(12) Patent Application Publication
(10) Pub. No.: US 2013/0176801 A1
(43) Pub. Date: Jul. 11, 2013

(54) PRECHARGE CIRCUIT AND SEMICONDUCTOR MEMORY DEVICE HAVING THE SAME

(71) Applicant: Ho Uk SONG, Icheon-si (KR)

(72) Inventor: Ho Uk SONG, Icheon-si (KR)

(73) Assignee: SK hynix Inc., Icheon-si (KR)

(21) Appl. No.: 13/493,510

(22) Filed: Jun. 11, 2012

(30) Foreign Application Priority Data
Jan. 5, 2012 (KR) 10-2012-0001717

(51) Int. Cl. G11C 7/00

(52) U.S. Cl. 365/203

(57) ABSTRACT

A semiconductor memory device includes: input/output line coupled to a first bit line of a first mat including a plurality of memory cells; a second input/output line coupled to a second bit line of a second mat including a plurality of memory cells; and a switching unit configured to couple the first input/output line and the second input/output line in response to a precharge signal.

### CROSS-REFERENCES TO RELATED APPLICATIONS

The present application claims priority under 35 U.S.C 119(a) to Korean Application No. 10-2012-0001717, filed on Jan. 5, 2012, in the Korean intellectual property Office, which is incorporated herein by reference in its entirety.

### BACKGROUND

In general, a semiconductor memory device performs a read operation of outputting data stored in a memory cell through a pad and a write operation of storing data, inputted through a pad, in a memory cell. In the read operation, the data stored in the memory cell is loaded into a bit line in response to a read command RD. The data loaded in the bit line is loaded into an input/output line in a period where a column select signal YI is enabled, and outputted through the pad via a global line. In the write operation, the data inputted through the pad is loaded into the input/output line via the global line. The data loaded in the input/output line is loaded into the bit line in the period where the column select signal YI is enabled, and then stored in the memory cell. The column select signal YI is enabled in synchronization with the read command RD and the write command WT. When a precharge operation is performed after the read or write operation is completed, the input/output line is precharged to a precharge voltage VBLP corresponding to a ½ level of a core voltage VCORE. When the precharge voltage VBLP is set at a ½ level of the core voltage VCORE, the semiconductor memory device may quickly sense and amplify the logic level of the stored data in the memory cell.

The semiconductor memory device includes a plurality of mats, each of which is a unit of a plurality of memory cell. In general, each of the mats includes a plurality of memory cells and a bit line coupled to the memory cells. The bit line and an input/output line are coupled by a switch which is turned on in a period where the column select signal YI is enabled.

In a known semiconductor memory device, the respective mats include input/output lines to input or output data, and the input/output lines coupled to the respective mats are separated from each other. The input/output lines coupled to the mats are precharged to the same precharge voltage. However, since the input/output lines are independently influenced by change in PVT (Process, Voltage, and Temperature) characteristics or input/output line characteristics, the precharge voltages may vary. When the precharge voltages of the input/output lines are different from each other, data input/output speed in the input/output lines may vary.

### SUMMARY

An embodiment of the present invention relates to a semiconductor memory device capable of precharging input/output lines coupled to mats to precharge voltages at the same level by coupling the input/output lines coupled to the mats during a precharge operation.

In an embodiment of the present invention, a precharge circuit includes: input/output line coupled to a first bit line of a first mat including a plurality of memory cells; a second input/output line coupled to a second bit line of a second mat including a plurality of memory cells; and a switching unit configured to couple the first input/output line and the second input/output line in response to a precharge signal.

In an embodiment of the present invention, a semiconductor memory device includes: a first mat including a first bit line coupled to a first input/output line in response to a column select signal which is generated by receiving a read or write command and decoding an address; a second mat including a second bit line coupled to a second input/output line in response to the column select signal; and a switching unit configured to couple the first input/output line and the second input/output line in response to a precharge signal.

In an embodiment of the present invention, a semiconductor memory device includes: a precharge circuit comprising: a first input/output line coupled to a first bit line; a second input/output line coupled to a second bit line; and a switching unit configured to couple the first input/output line and the second input/output line in response to a precharge signal.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram illustrating the configuration of a semiconductor memory device in accordance with an embodiment of the present invention;

FIG. 2 is a circuit diagram illustrating an example of a switching unit included in the semiconductor memory device of FIG. 1;

FIG. 3 is a circuit diagram illustrating another example of a switching unit included in the semiconductor memory device of FIG. 1; and

FIG. 4 is a timing diagram explaining the operation of the semiconductor memory device of FIG. 1.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

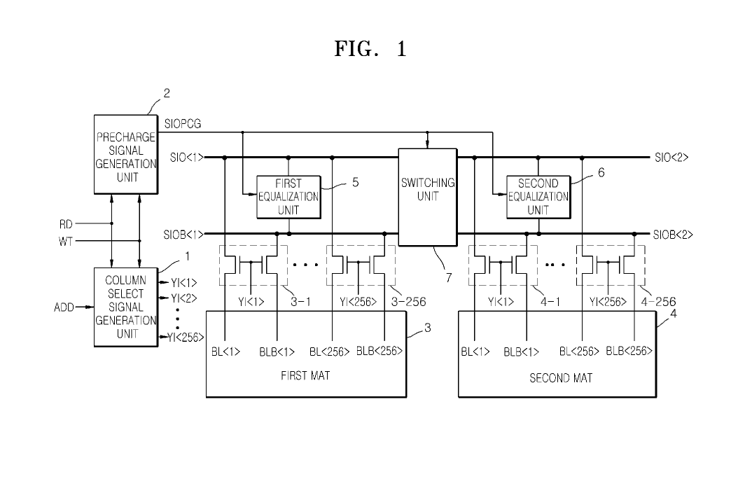

FIG. 1 is a block diagram illustrating the configuration of a semiconductor memory device in accordance with an embodiment of the present invention.

Referring to FIG. 1, the semiconductor memory device in accordance with an embodiment of the present invention includes a column select signal generation unit 1, a precharge signal generation unit 2, a first mat 3, first to 256th first mat switches 3-1 to 3-256 coupled to bit lines included in the first mat 3, a second mat 4, first to 256th second mat switches 4-1 to 4-256 coupled to bit lines included in the second mat 4, a first equalization unit 5, a second equalization unit 6, and a switching unit 7.

The column select signal generation unit 1 is configured to receive a read command RD or write command WT and decode an address ADD to generate first to 256th column select signals YI<1:256>. The first to 256th column select signals YI<1:256> may be enabled in response to the read command RD or write command WT.

The precharge signal generation unit 2 is configured to generate a precharge signal SIOPCG which is disabled in response to the read command RD or the write command WT and enabled at a time point where a read operation or write operation is completed.

Each of the first and second mats 3 and 4 includes a plurality of cells coupled to a plurality of word lines and bit lines, and is configured to store data in each of the cells. The first mat 3 includes first to 256th bit line pairs BL<1:256> and BLB<1:256>. The first to 256th first mat switches 3-1 to 3-256 are turned on in a period where the first to 256th column select signals YI<1:256> are enabled to a logic high level. The second mat 4 includes first to 256th bit pairs BL<1:256> and BLB<1:256>. The first to 256th second mat switches 4-1 to 4-256 are turned on in the period where the first to 256th column select signals YI<1:256> are enabled to a logic high level. Here, a first input/output line pair SIO<1> and SIOB<1> includes a first input/output line SIO<1> and a first input/output line bar SIOB<1>, and a second input/output line pair SIO<2> and SIOB<2> includes a second input/output line SIO<2> and a second input/output line bar SIOB<2>.

The first equalization unit 5 is configured to equalize the first input/output line SIO<1> and the first input/output line bar SIOB<1> to a precharge voltage when the precharge signal SIOPCG is enabled to a logic low level, and the second equalization unit 6 is configured to equalize the second input/output line SIO<2> and the second input/output line bar SIOB<2> to a precharge voltage when the precharge signal SIOPCG is enabled to a logic low level.

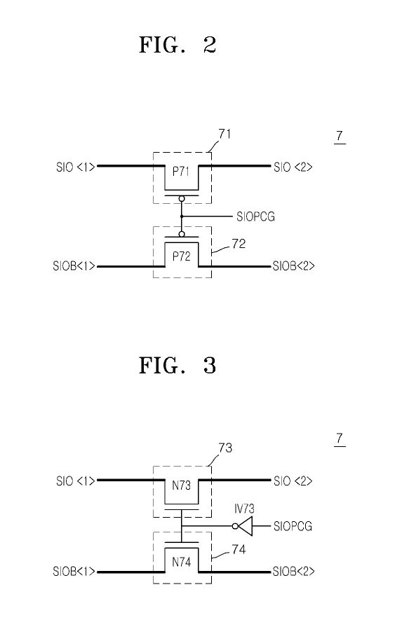

Referring to FIG. 2, the switching unit 7 may include an input/output switch 71 and a complementary input/output switch 72, for example. The switching unit 7 configured in such a manner couples the first input/output line SIO<1> and the second input/output line SIO<2>, and couples the first input/output line bar SIOB<1> and the second input/output line bar SIOB<2> in the period where the precharge signal SIOPCG is enabled to a logic low level.

Referring to FIG. 3, the switching unit 7 may include an input/output switch 73, a complementary input/output switch 74, and an inverter IV73, for another example. The switching unit 7 configured in such a manner couples the first input/output line SIO<1> and the second input/output line SIO<2>, and couples the first input/output line bar SIOB<1> and the second input/output line bar SIOB<2> in the period where the precharge signal SIOPCG is enabled to a logic low level.

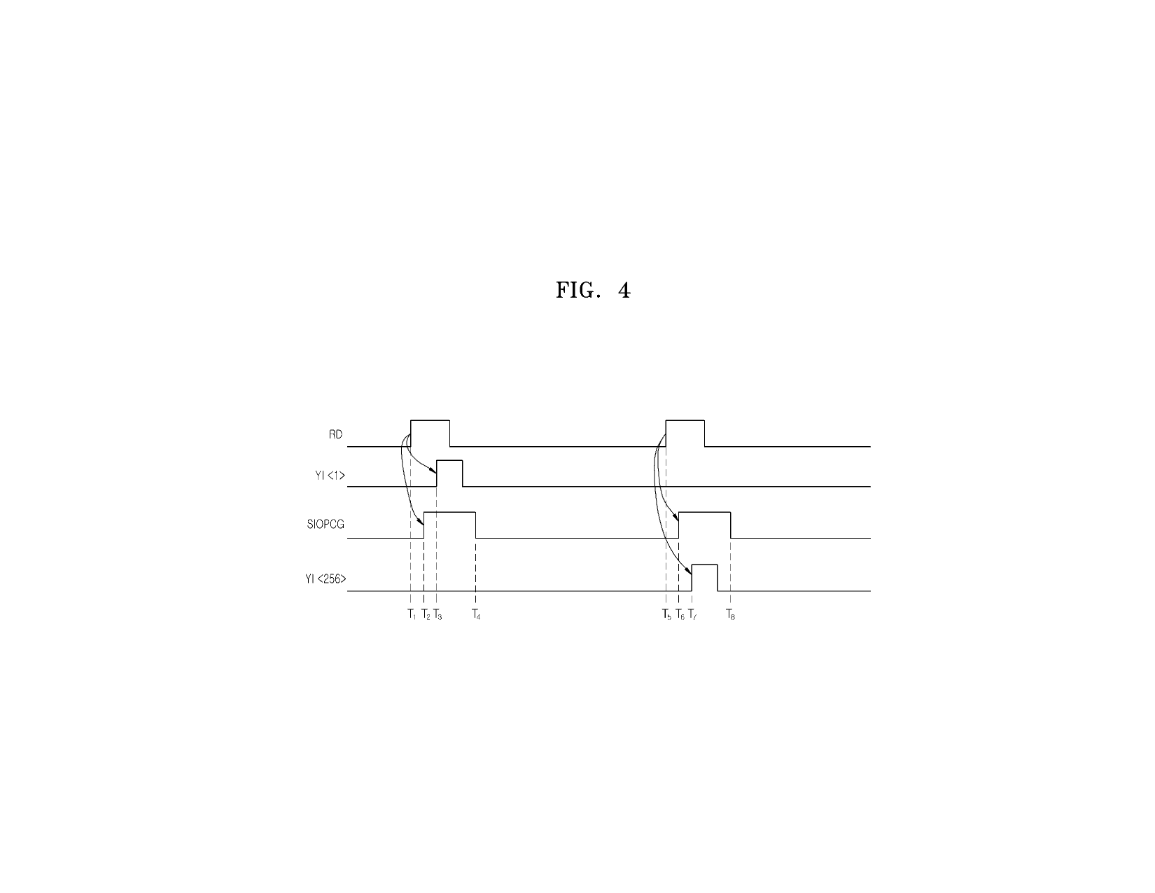

Referring to FIG. 4, the operation of the semiconductor memory device configured in the above-described manner will be described in detail. In the following descriptions, it is assumed that when the semiconductor memory device receives the read command RD, the first column select signal YI<1> and the 256th column select signal YI<256> are enabled.

First, when the semiconductor memory device receives the read command RD at a time point T1, the precharge signal SIOPCG is disabled to a logic high level in response to the read command RD at a time point T2. At a time point T3, the first column select signal YI<1> is enabled to a logic high level in response to the read command RD. At a time point T4, when the read operation of the semiconductor memory device is completed, the precharge signal SIOPCG is enabled to a logic low level. When the precharge signal SIOPCG is enabled to a logic low level, the first equalization unit 5 equalizes the first input/output line SIO<1> and the first input/output line bar SIOB<1> to a precharge voltage, and equalizes the second input/output line SIO<2> and the second input/output line bar SIOB<2> to a precharge voltage. Furthermore, the switching unit 7 couples the first input/output line SIO<1> and the second input/output line SIO<2>, and couples the first input/output line bar SIOB<1> and the second input/output line bar SIOB<2>. Therefore, the first input/output line of the first mat and the second input/output line of the second mat are precharged to the precharges voltages at the same level.

Then, when the semiconductor memory device receives the read command RD at a time point T5, the precharge signal SIOPCG is disabled to a logic high level in response to the read command RD at a time point T6. At a time point T7, the 256th column select signal YI<256> is enabled to a logic high level in response to the read command RD. At a time point T8, when the read operation of the semiconductor memory device is completed, the precharge signal SIOPCG is enabled to a logic low level. When the precharge signal SIOPCG is enabled to a logic low level, the first equalization unit 5 equalizes the first input/output line SIO<1> and the first input/output line bar SIOB<1> to a precharge voltage, and equalizes the second input/output line SIO<2> and the second input/output line bar SIOB<2> to a precharge voltage. Furthermore, the switching unit 7 couples the first input/output line SIO<1> and the second input/output line SIO<2>, and couples the first input/output line bar SIOB<1> and the second input/output line bar SIOB<2>. Therefore, the first input/output line of the first mat and the second input/output line of the second mat are precharged to the precharge voltages at the same level.

In various embodiments of the present invention, although PVT characteristics or input/output line characteristics vary when the semiconductor memory device performs a precharge operation, the semiconductor memory device couples the first input/output line of the first mat and the second input/output line of the second mat such that the first and second input/output lines are precharged to the precharge voltages at the same level. Therefore, it is possible to reduce a difference in data input/output speed.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor memory device comprising:
a first input/output line coupled to a first bit line of a first mat comprising a plurality of memory cells;
a second input/output line coupled to a second bit line of a second mat comprising a plurality of memory cells; and
a switching unit configured to couple the first input/output line and the second input/output line in response to a precharge signal.

2. The semiconductor memory device of claim 1, further comprising:
a first input/output line bar coupled to a first bit line bar of the first mat; and
a second input/output line bar coupled to a second bit line bar of the second mat,
wherein the switching unit couples the first input/output line bar and the second input/output line bar in response to the precharge signal.

3. The semiconductor memory device of claim 2, wherein the precharge signal is disabled in response to a read command or write command and enabled at a time point where a read operation or write operation is completed.

4. The semiconductor memory device of claim 2, wherein the switching unit couples the first input/output line and the second input/output line and couples the first input/output line bar and the second input/output line bar, in response to the precharge signal.

5. The semiconductor memory device of claim 3, wherein the switching unit comprises:
an input/output switch configured to couple the first input/output line and the second input/output line in response to the precharge signal; and
a complementary input/output switch configured to couple the first input/output line bar and the second input/output line bar in response to the precharge signal.

6. The semiconductor memory device of claim 2, further comprising:
a first equalization unit configured to equalize the first input/output line and the first input/output line bar to a precharge voltage in response to the precharge signal; and
a second equalization unit configured to equalize the second input/output line and the second input/output line bar to the precharge voltage in response to the precharge signal.

7. A semiconductor memory device comprising:
a first mat comprising a first bit line coupled to a first input/output line in response to a column select signal which is generated by receiving a read or write command and decoding an address;
a second mat comprising a second bit line coupled to a second input/output line in response to the column select signal; and
a switching unit configured to couple the first input/output line and the second input/output line in response to a precharge signal.

8. The semiconductor memory device of claim 7, wherein the first mat further comprises a first input/output line bar coupled to a first bit line bar in response to the column select signal,
the second mat further comprises a second input/output line bar coupled to a second bit line bar in response to the column select signal, and
the switching unit couples the first input/output line bar and the second input/output line bar in response to the precharge signal.

9. The semiconductor memory device of claim 8, wherein the precharge signal is disabled in response to the read or write command and enabled at a time point where a read or write operation is completed.

10. The semiconductor memory device of claim 8, wherein the switching unit couples the first input/output line and the second input/output line and couples the first input/output line bar and the second input/output line bar, in response to the precharge signal.

11. The precharge circuit of claim 10, wherein the switching unit comprises:
an input/output switch configured to couple the first input/output line and the second input/output line in response to the precharge signal; and
a complementary input/output switch configured to couple the first input/output line bar and the second input/output line bar in response to the precharge signal.

12. The semiconductor memory device of claim 8, further comprising:
a first equalization unit configured to equalize the first input/output line and the first input/output line bar to a precharge voltage in response to the precharge signal; and
a second equalization unit configured to equalize the second input/output line and the second input/output line bar to the precharge voltage in response to the precharge signal.

13. A precharge circuit comprising:
a first input/output line coupled to a first bit line;
a second input/output line coupled to a second bit line; and
a switching unit configured to couple the first input/output line and the second input/output line in response to a precharge signal.

14. The precharge circuit of claim 13, further comprising:
a first input/output line bar coupled to a first bit line bar; and
a second input/output line bar coupled to a second bit line bar,
wherein the switching unit couples the first input/output line bar and the second input/output line bar in response to the precharge signal.

15. The precharge circuit of claim 14, wherein the precharge signal is disabled in response to a read command or write command and enabled at a time point where a read operation or write operation is completed.

16. The precharge circuit of claim 14, wherein the switching unit couples the first input/output line and the second input/output line and couples the first input/output line bar and the second input/output line bar, in response to the precharge signal.

17. The precharge circuit of claim 15, wherein the switching unit comprises:
an input/output switch configured to couple the first input/output line and the second input/output line in response to the precharge signal; and
a complementary input/output switch configured to couple the first input/output line bar and the second input/output line bar in response to the precharge signal.

18. The precharge circuit of claim 14, further comprising:
a first equalization unit configured to equalize the first input/output line and the first input/output line bar to a precharge voltage in response to the precharge signal; and
a second equalization unit configured to equalize the second input/output line and the second input/output line bar to the precharge voltage in response to the precharge signal.
